(19) United States
(12) Patent Application Publication
(10) Pub. No.: US 2011/0204913 A1
(43) Pub. Date: Aug. 25, 2011

(54) TEST SECTION UNIT AND TEST HEAD

(76) Inventor: Satoshi Takeshita, Tokyo (JP)

(21) Appl. No.: 13/062,712

(22) PCT Filed: Sep. 26, 2008
(86) PCT No.: PCT/JP2008/067531

§ 371 Date: May 3, 2011

(51) Int. Cl. G01R 31/00

(52) U.S. Cl. 324/756.01

(57) ABSTRACT

A test section unit 7 comprising a handle 6 which is detachable without using any tool: wherein the handle 6 comprises a base plate 61, two brackets 62 provided to both end portions of the base plate 61, a handle bar 63 bridging over between the both brackets 62, and two guide shafts and two index plungers 65 provided to the base plate 61; while a performance board 51 of a test section unit body 5 has two guide holes 53 extending in the plane direction of the performance board 51 and two plunger holes 54 extending in the thickness direction of the performance board 51 formed thereon.

### TECHNICAL FIELD

The present invention relates to a test head, which is used in an electronic device testing apparatus, and a test section unit mounted on a body part of the test head in an attachable/detachable way.

### BACKGROUND ART

In a production procedure of an electronic device, such as an IC device, a testing apparatus for testing a finally produced electronic device is necessary. In such a testing apparatus, an electronic device handling apparatus called a handler conveys IC devices and brings external terminals of the respective IC devices electrically contact with connection terminals of sockets provided on a test head to conduct a test by a main testing device (tester). In this way, IC devices are tested and classified to categories of at least good ones and defective ones.

A test section unit (referred to as a Hi-Fix or mother board in some cases) is generally provided on the test head. The test section unit is provided with a performance board having a function of an adopter and a socket board, which is electrically connected to the performance board and has one or more sockets. The test section unit is attached to the test head body and can be replaced.

Here, a plurality of substrates are provided inside the test head body and, for example, when a trouble occurs on a substrate or when a kind of IC devices to be tested is changed, the test section unit has to be detached from the test head body for maintenance of the test head body or replaced with a different test section unit in some cases.

As shown in FIG. 7, a test section unit 7P of the related art comprises a test section unit body 5P and handles 6P provided to both side portions of the test section unit body 5P. Each of the handles 6P comprises two brackets 62P fixed to the test section unit body 5P with screws, etc. and a pipe-shaped handle bar 63P bridging over between the brackets 62P. A length of the handle 6P is approximately the same as a width of the test section unit body 5P.

Since the test section unit 7P is heavy as about 60 kg, four operators are necessary to detach/attach the test section unit 7P by holding the handles 6P. However, the handle 6P is too short for two operators to hold and does not have a length appropriate to the product weight based on ergonomics. Accordingly, the test section unit 7P had to be detached/attached in an unstable condition before.

On the other hand, when the length of the handle 6P becomes longer than the width of the test section unit body 5P, it interferes with other components. Therefore, the maximum length of the handle 6P is the width of the test section unit body 5P.

Also, the pipe-shaped handle bar 63P of the handle 6P sometimes ends up becoming an antenna for receiving electromagnetic interference (EMI) depending on its specification.

### DISCLOSURE OF THE INVENTION

The present invention was made in consideration of the above circumstances and has as an object thereof to provide a test section unit and a test head, wherein a handle can be designed to have a size appropriate to the product weight and the handle can prevent from receiving electromagnetic interference.

To attain the above object, according to the first aspect of the present invention, there is provided a test section unit to be mounted on a body part of a test head, characterized by comprising a handle which can be detached/attached without using any tool (Invention 1).

According to the invention above (Invention 1), since the handle can be detachable, reception of electromagnetic interference by the handle can be prevented by detaching the handle after mounting the test section unit on the test head body part, and the handles do not interfere with other components even when they are made to have a size appropriate to the product weight based on ergonomics.

In the invention above (Invention 1), the handle may comprise an elongated holder portion (Invention 2).

In the invention above (Invention 2), a length of the handle may be longer than a width of the test section unit (Invention 3). Due to this, the handles can be designed to have a size appropriate to the product weight based on ergonomics, so that it becomes easy for operators to hold the handles and detaching/attaching of the test section unit from/to the body part of the test head can be done in a stable condition.

In the invention above (Invention 1), the test section unit is mounted by the number of two or more in parallel on the body part of the test head, and one set of the handles may be used for the plurality of test section units (Invention 4).

In the invention above (Invention 1), preferably, the handle is attached to the body part of the test section unit as a result that a pin and a hole both extending in the plane direction of the test section unit engage with each other and a pin and a hole both extending in the thickness direction of the test section unit engage with each other, and detached from the body part of the test section unit as a result that the respective pins are pulled out from the respective holes (Invention 5).

In the invention above (Invention 5), a pin and a hole extending in the thickness direction of the test section unit can give a function of locking and unlocking the attachment of the handle to the body part of the test section unit.

In the invention above (Invention 5), alternatively, the handle comprises a first pin extending in the plane direction of the test section unit and a second pin extending in the thickness direction of the test section unit, and the body part of the test section unit has a first hole extending in the plane direction of the test section unit and a second hole extending in the thickness direction of the test section unit formed thereon (Invention 6).

In the invention above (Invention 6), preferably, the second pin of the handle is movable in the thickness direction of the test section unit and, by moving the second pin, locking and unlocking of attachment of the handle to the body part of the test section unit is done.

In the invention above (Invention 7), preferably, the handle is provided with an index plunger and the second pin is a movable pin belonging to the index plunger (Invention 8). By using the index plunger, locking and unlocking of the attachment of the handle to the body part of the test section unit can be done extremely easily in a short time. Also, due to the locking by the index plunger, the handle is prevented from falling from the body part of the test section unit and it is highly secure.

In the invention above (Invention 8), preferably, the handle comprises a base plate attached firmly to a side surface of the body part of the test section unit, brackets provided to both end portions of the base plate and a handle bar bridging over between the both brackets; the first pin is provided to the base plate and protruding toward the body part of the test section unit; and the index plunger is provided to the base plate so that the second pin is movable in the thickness direction of the test section unit (Invention 9).

In the invention above (Invention 6), preferably, the handle comprises a plurality of the first pins (Invention 10). Due to this, a force for fixing the handle to the body part of the test section unit can be secured.

In the invention above (Invention 8), preferably, the handle comprises two of the index plungers (Invention 11). Due to this, the index plungers can be operated with right and left hands of one operator, so that the handle can be detached/attached easily by one operator.

Secondly, the present invention provides a test head characterized by comprising a test head body and a test section unit (Invention 1) mounted on the test head body (Invention 12).

Thirdly, the present invention provides a test head, characterized by comprising a test head body and a test section unit (Invention 4) mounted by the number of two or more in parallel on the test head body (Invention 13).

According to the present invention, since the handle can be detached/attached, reception of electromagnetic interference by the handle can be prevented by detaching the handle after mounting the test section unit on the body part of the test head. Also, even when a size of the handle is designed to be appropriate to a weight of the test section unit, for example, when it is designed to be longer than a width of the body part of the test section unit, it is possible to prevent the handle from interfering with other components by detaching the handle after mounting the test section unit on the body part of the test head.

### BRIEF DESCRIPTION OF DRAWINGS

FIG. 1 is a side view of a test head unit and a handler according to an embodiment of the present invention.

FIG. 2 is a perspective view of body parts of test section units (in parallel) according to the same embodiment.

FIG. 3A and FIG. 3B are perspective views of a handle of the test section unit according to the same embodiment.

FIG. 4 is a perspective view of the test section units (in parallel) according to the same embodiment.

FIG. 5 is a perspective view of a test section unit (single) according to the same embodiment.

FIG. 6 is a perspective view of a body part of the test section unit (single) according to the same embodiment.

FIG. 7 is a perspective view of a test section unit of the related art.

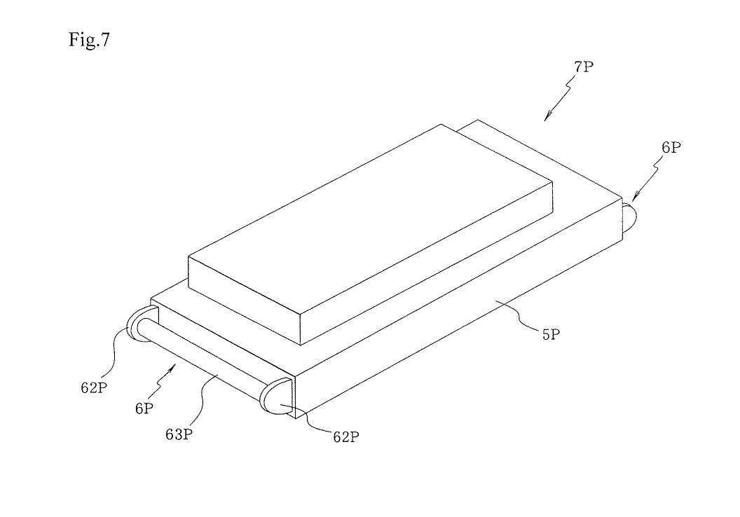

### BEST MODE FOR CARRYING OUT THE INVENTION

Below, an embodiment of the present invention will be explained based on the drawings.

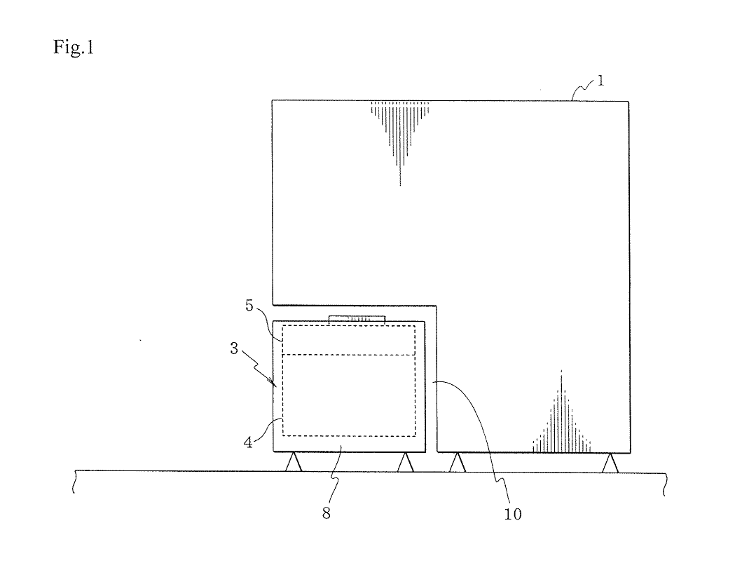

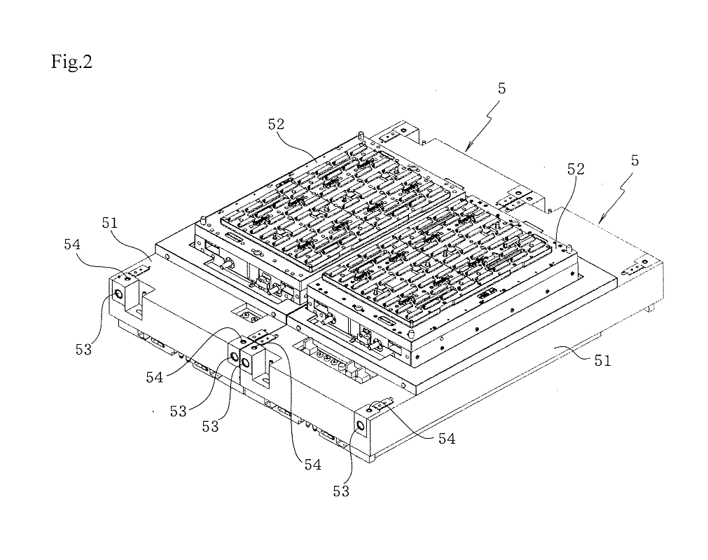

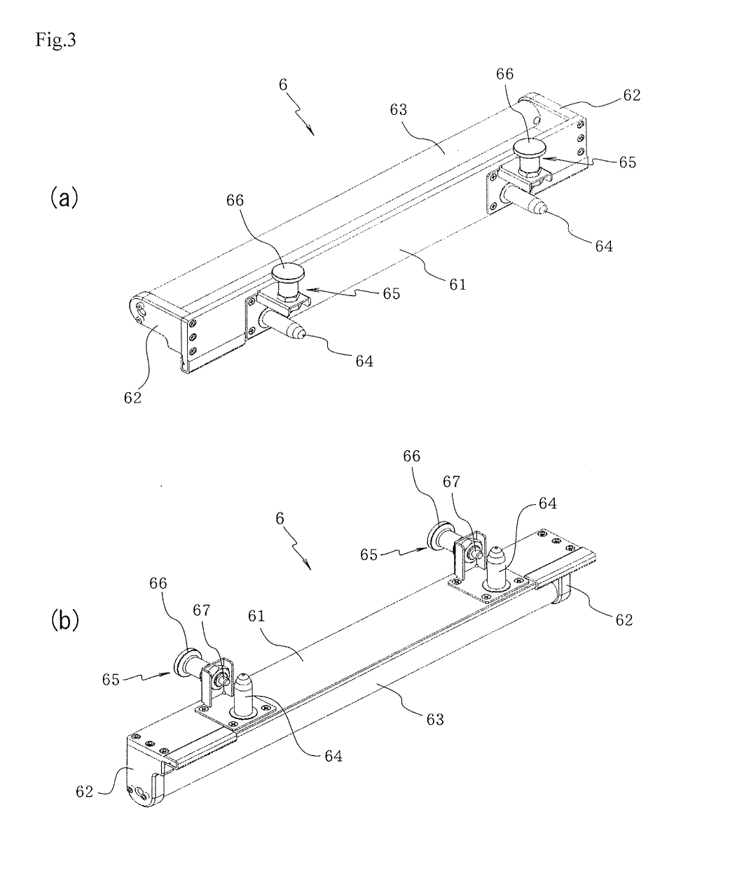

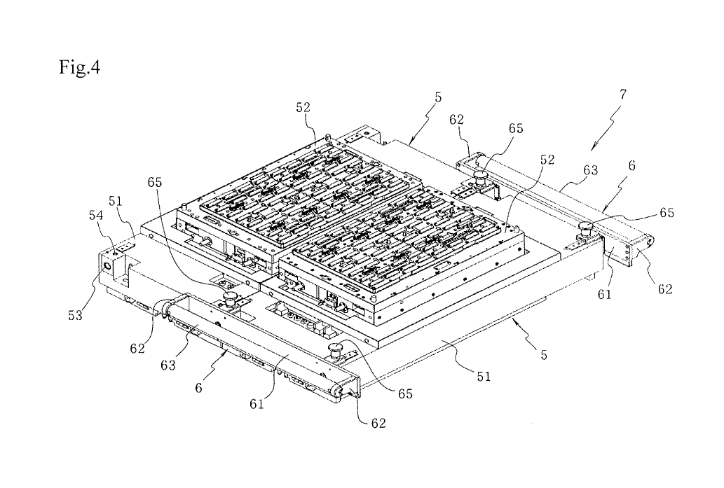

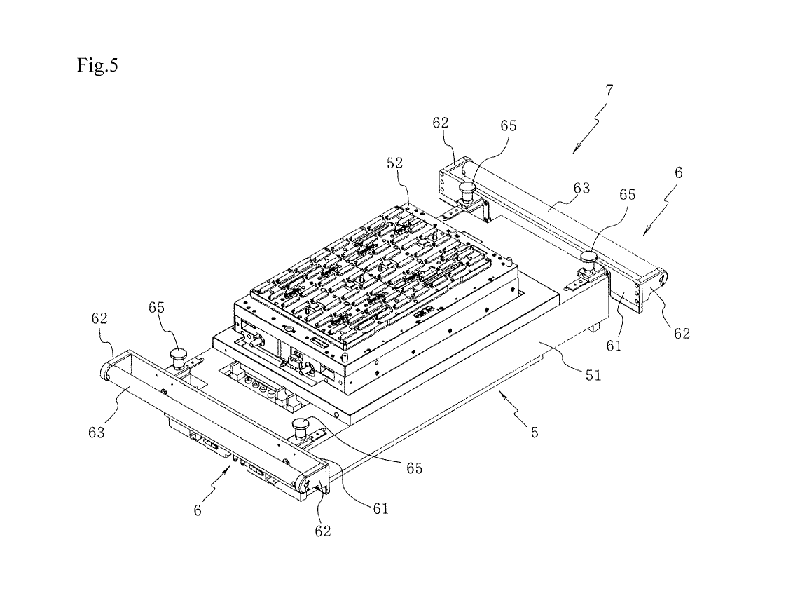

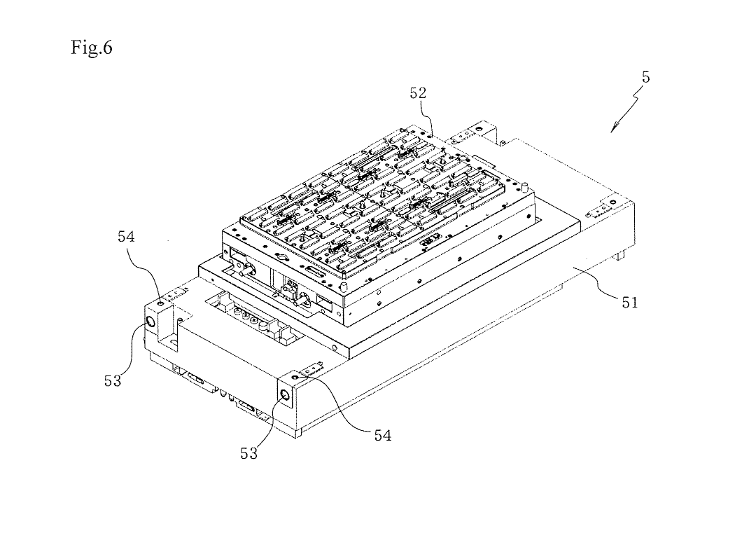

FIG. 1 is a side view of a test head unit and a handler according to an embodiment of the present invention, FIG. 2 is a perspective view of body parts of test section units (in parallel) according to the same embodiment, FIG. 3A and FIG. 3B are perspective views of a handle of the test section unit according to the same embodiment, FIG. 4 is a perspective view of the test section units (in parallel) according to the same embodiment, FIG. 5 is a perspective view of a test section unit (single) according to the same embodiment, and FIG. 6 is a perspective view of a body part of the test section unit (single) according to the same embodiment.

As shown in FIG. 1, the IC device testing apparatus comprises a handler 1, a test head 3 and a not shown main testing device. The handler 1 performs an operation of successively conveying IC devices (an example of electronic devices) to be tested to sockets provided to the test head 3, classifying IC devices finished with the test in accordance with the test results and storing in predetermined trays.

In the lower portion of the handler 1, a control device for mainly controlling the handler 1 is incorporated and a space 10 is provided to a part thereof. The test head 3 is placed in the space 10 in a freely replaceable way, and IC devices can be attached to the sockets on the test head 3 through a through hole formed on the handler 1.

The test head 3 is placed in a test head moving device 8 and comprises a test head body 4 incorporating a plurality of substrates and a test section unit body 5 provided on top of the test head body 4. Note that the test head 3 and the test head moving device 8 are collectively called as a test head unit in this specification.

The test head moving device 8 has a slide mechanism. By driving the slide mechanism, the test head 3 is drawn from the test head moving device 8 and taken out from the handler 1. As a result, a detaching/attaching operation of the test section unit body 5 from/to the test head body 4 can be carried out.

In the present embodiment, as shown in FIG. 2, the test head body 4 is provided with two test section unit bodies 5 in parallel. Each of the test section unit bodies 5 has a performance board 51 and a socket board 52, which is electrically connected to the performance board 51 and provided with a plurality of sockets. Each of the test section unit bodies 5 is attached to the test head body 4 via a connector and is replaceable.

The sockets provided on the socket board 52 are electrically connected to the main testing device via substrates inside the test head body 4 and a not shown outer cable. IC devices attached to the sockets are connected to the main testing device and tested by a testing electric signal from the main testing device.

On both end portions of both side surfaces of the performance board 51 of each of the testing section unit bodies 5, guide holes 53 extending in the plane direction of the performance board 51 are formed. Also, at four corners of an upper surface of the performance board 51, plunger holes 54 extending in the thickness direction of the performance board 51 are formed.

As shown in FIG. 4 and FIG. 5, handles 6 are attached to the test section unit body 5 in a detachable way. Two handles 6 make up one set, and one set of handles 6 is used for two test section unit bodies 5. In the present embodiment, the test section unit bodies 5 and the handles 6 are collectively called a test section unit 7.

As shown in FIG. 3, the handle 6 has a base plate 61 to be attached firmly to a side surface of the performance board 51. On both end portions of one surface of the base plate 61 (the opposite surface of the performance board 51), two brackets 62 are provided, and a pipe-shaped handle bar 63 bridges over between the brackets 62. On the other surface of the base plate 61 (the surface on the performance board 51 side), two guide shafts 64 are provided to be protruding toward the performance board 51 side, and an index plunger 65 is provided on the upper side of each of the guide shafts 64. The index plunger 65 has a plunger pin 67 being movable to be protruding and receded and a knob 66 for operating the plunger pin 67. Note that the plunger pin 67 is biased by a not shown spring in the direction that the index plunger 65 protrudes. The index plunger 65 is provided to the base plate 61, so that the plunger pin 67 is movable in the thickness direction of the performance board 51.

A size of the guide shaft 64 of the handle 6 and that of the guide hole 53 formed on the performance board 51 are set to fit each other, and a size of the plunger pin 67 of the index plunger 65 and that of the plunger hole 54 formed on the performance board 51 are set to fit each other.

To attach the handle 6 to the test section unit body 5, in a state that the knobs 66 of the index plungers 65 are lifted upward and the plunger pins 67 are receded inside the index plungers 65, the guide shafts 64 of the handle 6 are inserted in the guide holes 53 on the performance board 51 and the base plate 61 of the handle 6 is attached firmly to the side surface of the performance board 51. Then, by releasing hands from the knobs 66, the knobs 66 of the index plungers 65 are put back to the original positions, and the plunger pins 67 are protruded from inside the index plungers 65 and inserted to the plunger holes 54 of the performance board 51. As a result, the handle 6 and the test section unit body 5 are locked and it is possible to prevent the handle 6 from falling from the test section unit body 5. The test section unit 7, wherein the handle 6 is attached to the test section unit body 5, is shown in FIG. 4 and FIG. 5.

On the other hand, to detach the handle 6 from the test section unit body 5, the knobs 66 of the index plungers 65 are lifted upward and the plunger pins 67 are pulled out from the plunger holes 54 of the performance board 51 so as to unlock the handle 6 from the test section unit body 5. Then, the handle 6 is detached from the test section unit body 5, the guide shafts 64 of the handle 6 are pulled out from the guide holes 53 of the performance board 51 and finally, by releasing hands from the knobs 66 of the index plunger 65, the knobs 66 are put back to the original positions. The test section unit body 5, wherein the handle 6 is removed from the test section unit 7, is shown in FIG. 2 and FIG. 6.

Since there are two index plungers 65 on the handle 6, by operating the knobs 66 of the index plungers 65 respectively with right and left hands by one operator, attaching/detaching of the handle 6 to/from the test section unit body 5 can be remarkably easily attained in a short time (a few seconds) without using any tool.

A length of the handle 6 is designed to be appropriate to the product weight (weight of the test section unit body 5) based on ergonomics, and it is longer than a width of the test section unit body 5 in the present embodiment as shown in FIG. 4 and FIG. 5. Because the handle 6 is detachable from the test section unit body 5, even if the length of the handle 6 is longer than the test section unit body 5 as above, it is possible to prevent the handle 6 from interfering with other components (for example, including other handle) when the handle 6 is detached from the test section unit body 5. Also, the handle bar 63 of the handle 6 sometimes becomes an antenna for receiving electromagnetic interference, however, such problem can be solved by removing the handle 6 from the test section unit body 5 when using the test head 3.

Note that the length of the handle bar 63 of the handle 6 can be easily changed in accordance with a size and weight of the test section unit body 5. While the length is set to be suitable for two operators to hold in the present embodiment, the length may be changed to be suitable for three or four operators to hold, as well.

A method of detaching/attaching the test section unit body 5 from/to the test head body 4 will be explained here.

First, by driving the slide mechanism of the test head moving device 8, the test head 3 is pulled out from the test head moving device 8 and taken out from the handler 1. Then, as shown in FIG. 4, the handles 6 are attached respectively to both side portions of one of the test section unit bodies 5. As explained above, attachment of the handles 6 can be done extremely easily in a short time by operating the index plungers 65.

Two operators hold each of the handles 6 attached to the test section unit body 5, a total of four operators lift the test section unit 7, detach it from the test head body 4 and place the detached test section unit 7 (refer to FIG. 5) on a desired position.

At this time, a length of the handles 6 is longer than a width of the test section unit body 5, which is an appropriate length to the product weight based on ergonomics, so that it is easy to hold the handles 6 for all operators. Therefore, the test section unit 7 can be detached/attached in a stable condition.

Also, because the handles 6 and the test section unit body 5 are locked by the index plungers 65, the handles 6 cannot fall from the test section unit body 5 during detaching/attaching the test section unit 7. Namely, in order to unlock, the handle 6 has to be pulled from the test section unit body 5 while intentionally lifting the knobs 66 of the index plungers 65, which means that the lock is not released naturally and it is safe and secure.

Next, as shown in FIG. 6, the handles 6 are detached from the test section unit 7. As explained above, detaching of the handles 6 can be also done extremely easily in a short time by operating the index plungers 65.

The detached handles 6 are attached to the other test section unit body 5 in the same way as above and, by holding the attached handles 6, the test section unit 7 is lifted and detached from the test head body 4.

After completing maintenance of the test head body 4, the two test section unit bodies 5 are attached to the test head body 4 through an inverse operation from the above, and the handles 6 are detached from the test section unit bodies 5 (refer to FIG. 2). It is in the same way when exchanging the test section unit bodies 5 to different ones: two other test section unit bodies 5 are attached to the test head body 4 through an inverse operation from the above, and the handles 6 are detached from the test section unit bodies 5 (refer to FIG. 2). By removing the handles 6 from the test section unit bodies 5 as such, reception of electromagnetic interference caused by the handles 6 can be prevented when using the test head 3.

Finally, by driving the slide mechanism of the test head moving device 8, the test head 3 is restored to the original position in the test head moving device 8.

The embodiments explained above are described to facilitate understanding of the present invention and are not to limit the present invention. Accordingly, respective elements disclosed in the above embodiments include all design modifications and equivalents belonging to the technical scope of the present invention.

For example, the number of guide shafts 64 and that of guide holes 53 are not limited to two and may be changed arbitrarily in accordance with a size and weight of the test section unit body 5. Also, a solenoid plunger for protruding and receding a pin by electromagnetic solenoid may be used instead of an index plunger 65, or a pin which can be protruding and receded manually may be used, as well. Furthermore, the handles 6 may be detached from or attached to the test section unit body 5 by turning on/off a magnetic force of an electromagnet, etc.

### INDUSTRIAL APPLICABILITY

The present invention is useful for detaching/attaching a test section unit body from/to a test head body and preventing electromagnetic interference in a test head.

1. A test section unit to be mounted on a body part of a test head, comprising a handle which can be attached/detached without using any tool.

2. The test section unit as set forth in claim 1, wherein the handle comprises an elongated holder portion.

3. The test section unit as set forth in claim 2, wherein a length of the handle is longer than a width of the test section unit.

4. The test section unit as set forth in claim 1, wherein the test section unit is mounted by the number of two or more in parallel on the body part of the test head, and one set of the handles is used for the plurality of test section units.

5. The test section unit as set forth in claim 1, wherein the handle is attached to the body part of the test section unit as a result that a pin and a hole both extending in the plane direction of the test section unit engage with each other and a pin and a hole both extending in the thickness direction of the test section unit engage with each other, and detached from the body part of the test section unit as a result that the respective pins are pulled out from the respective holes.

6. The test section unit as set forth in claim 5, wherein:
the handle comprises a first pin extending in the plane direction of the test section unit and a second pin extending in the thickness direction of the test section unit, and
the body part of the test section unit has a first hole extending in the plane direction of the test section unit and a second hole extending in the thickness direction of the test section unit formed thereon.

7. The test section unit as set forth in claim 6, wherein the second pin of the handle is movable in the thickness direction of the test section unit and, by moving the second pin, locking and unlocking of attachment of the handle to the body part of the test section unit is done.

8. The test section unit as set forth in claim 7, wherein the handle is provided with an index plunger and the second pin is a movable pin belonging to the index plunger.

9. The test section unit as set forth in claim 8, wherein:
the handle comprises a base plate attached firmly to a side surface of the body part of the test section unit, brackets provided to both end portions of the base plate and a handle bar bridging over between the both brackets;
the first pin is provided to the base plate and protruding toward the body part of the test section unit; and
the index plunger is provided to the base plate so that the second pin is movable in the thickness direction of the test section unit.

10. The test section unit as set forth in claim 6, wherein the handle comprises a plurality of the first pins.

11. The test section unit as set forth in claim 8, wherein the handle comprises two of the index plungers.

12. A test head, comprising:
a test head body, and
a test section unit as set forth in claim 1 mounted on the test head body.

13. A test head, comprising:
a test head body; and
a test section unit as set forth in claim 4 mounted by the number of two or more in parallel on the test head body.
